(19) United States
(12) Patent Application Publication
(10) Pub. No.: US 2006/0110534 A1
(43) Pub. Date: May 25, 2006

(54) Methods and apparatus for forming a titanium nitride layer

(75) Inventors: Wan-Goo Hwang, Yongin-si (KR); Seung-Ki Chae, Seoul (KR); Young-Kyou Park, Seoul (KR); Jung-Il Ahn, Suwon-si (KR); Kyoung-Ho Jang, Ansan-si (KR); Myeong-Jin Kim, Pyeongtaek-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/281,774

(22) Filed: Nov. 17, 2005

(30) Foreign Application Priority Data
Nov. 19, 2004 (KR) 10-2004-0094986

(51) Int. Cl. C23C 16/00; B05C 11/00

(52) U.S. Cl. 427/248.1; 118/715; 118/704; 118/730; 118/702

(57) ABSTRACT

A method of forming titanium nitride layers by an atomic layer deposition process using a batch-type vertical reaction furnace is described wherein the titanium nitride layers are formed on one or more substrates in accordance with a reaction between a first source gas including TiCl₄ gas and a second source gas including an NH₃ gas. After forming the titanium nitride layers, chlorine remaining in the titanium nitride layers is removed using a treatment gas which includes an NH₃ gas. The substrates are revolved by a predetermined rotation angle between repeated titanium nitride layer formation cycles. The process of forming the titanium nitride layers and rotating the substrates is alternately repeated resulting in titanium nitride layers having substantially uniform thicknesses and low specific resistance.

This application claims the benefit of priority under 35 USC § 119 to Korean Patent Application No. 2004-94986 filed Nov. 19, 2004, the disclosure of which is incorporated herein by reference in its entirety.

### BACKGROUND OF THE INVENTION

1. Field of the Invention

Example embodiments of the present invention relate to methods used in forming a layer on a substrate and to an associated apparatus for forming the layer on the substrate. More particularly, example embodiments of the present invention relate to methods of forming a titanium nitride (TiN) layer on a semiconductor substrate and to an apparatus for forming the titanium nitride layer on the semiconductor substrate.

2. Description of the Related Art

Semiconductor devices are typically manufactured by executing various sequential processes on suitable semiconductor substrates such as on silicon wafers. For example, a deposition process is generally performed for forming a layer on a semiconductor substrate, and/or an oxidation process is typically carried out for forming an oxide layer on the semiconductor substrate or for oxidizing a layer previously formed on the semiconductor substrate. Additionally, a photolithography process is commonly carried out for forming a desired pattern on the semiconductor substrate by etching a layer formed on the semiconductor substrate. Further, a planarization process is typically performed for planarizing a layer formed on the semiconductor substrate.

Various layers of a semiconductor device may be formed through a chemical vapor deposition (CVD) process, a physical vapor deposition (PVD) process, an atomic layer deposition (ALD) process, etc. For example, a silicon oxide layer serving as a gate insulation layer or an insulating interlayer of a semiconductor device is usually formed by a CVD process. A silicon nitride layer serving as a mask pattern or a gate spacer is also typically formed by a CVD process. Additionally, various metal layers, such as metal wirings and electrodes, of the semiconductor device may also typically be formed by a CVD process, a PVD process, an ALD process, etc.

In a semiconductor device, a titanium nitride layer may be used as a metal barrier layer to prevent a metal from diffusing. Such a titanium nitride layer may be formed by a CVD process, a PVD process, an ALD process, etc. Such a titanium nitride layer may also serve as a metal wiring, a contact plug, or an upper electrode of a capacitor so as to prevent diffusion of metal ions toward a lower region of a semiconductor device, such as toward a gate of a transistor, a dielectric layer of a capacitor or the semiconductor substrate, where the metal could adversely affect the performance of the semiconductor device. Conventional methods of forming a titanium nitride layer are disclosed in U.S. Pat. No. 6,436,820 issued to Hu et al., U.S. Pat. No. 6,555,183 issued to Wang et al., and U.S. Patent Application Publication No. 2003/0186560, each of which is incorporated herein by reference.

When the titanium nitride layer is included in the upper electrode of the capacitor, the titanium nitride layer serves as a metal barrier layer formed on the dielectric layer. In such applications, a doped polysilicon layer that serves as part of the upper electrode, or alternatively a metal layer, is typically additionally formed on the titanium nitride layer.

In recent years, a unit cell of commerical semiconductor devices has gradually become greatly reduced in size as the semiconductor devices have increasingly become highly integrated. Hence, developments in semiconductor manufacturing technology have focused on obtaining proper structures in the reduced-sized unit cells. For example, the dielectric layer or the gate insulation layer is formed using a material having a relatively high dielectric constant, whereas the insulating interlayer is formed using a material having a relatively low dielectric constant to reduce a parasitic capacitance. Materials having a suitably high dielectric constant for such applications include Y₂O₃, HfO₂, ZrO₂, Nb₂O₅, BaTiO₃, SrTiO₃, etc.

It has been found that if the dielectric layer is formed using HfO₂, and the titanium nitride layer is formed on the dielectric layer by a CVD process, hafnium (IV) chloride (HfCl₄) may be generated by a reaction between HfO₂ and a TiCl₄ gas used as a source gas for forming the titanium nitride layer. Hafnium (IV) chloride may adversely affect the dielectric characteristics of the dielectric layer. Further, chlorine ions remaining in the titanium nitride layer may also damage the semiconductor device by increasing a specific resistance of the titanium nitride layer, thereby augmenting a contact resistance between the dielectric layer and the upper electrode including the titanium nitride layer. For example, the titanium nitride layer has been found to have a relatively high specific resistance of about 420 μΩcm when the titanium nitride layer is formed using a TiCl₄ gas and an NH₃ gas.

In a conventional method of forming a titanium nitride layer, the titanium nitride layer is formed at a temperature of about 680° C. in accordance with the reaction between TiCl₄ gas and NH₃ gas. The residual chlorine ions contained in the resulting titanium nitride layer may be reduced by increasing a reaction temperature of the TiCl₄ gas and the NH₃ gas. Using such a higher reaction temperature, however, is limited by the tradeoff that the step coverage of the titanium nitride layer may be improved as the reaction temperature is decreased.

In a batch-type vertical chemical vapor deposition (CVD) apparatus as disclosed in the above-mentioned U.S. Patent Application Publication No. 2003/0186560, a titanium nitride layer formed on a substrate may have irregular thickness depending on a distance between the substrate and a gas outlet or a direction in which source gases flow onto the substrate. Additionally, a process time for forming the titanium nitride layer may be greatly increased when the titanium nitride layer is formed using the described apparatus and an ALD process in which a TiCl₄ gas and an NH₃ gas are employed as the source gases.

These and other limitations of and problems with prior art techniques for forming a titanium nitride layer in a semiconductor device are overcome in whole or at least in part by the methods and apparatus of this invention.

### SUMMARY OF THE INVENTION

Example embodiments of the present invention provide a method of rapidly forming a titanium nitride layer as part of a semiconductor element such that the titanium nitride layer has substantially uniform thickness, good step coverage and low specific resistance, and is formed without causing damage to an underlying layer of the semiconductor element.

Example embodiments of the present invention further provide an apparatus for forming a titanium nitride layer having substantially uniform thickness, good step coverage and low specific resistance without causing damage to an underlying layer.

According to one aspect of the present invention, there is provided a method of forming a titanium nitride layer. In one method of forming a titanium nitride layer according to the present invention, a titanium nitride layer is formed on a substrate loaded in a process chamber by contacting a first source gas which includes an effective amount of titanium and chlorine and a second source gas which includes an effective amount of nitrogen with the substrate. Multiple substrates can be loaded into the process chamber and treated simultaneously as here described to form a titanium nitride layer on each one. The first source gas and the second source gas are directed to flow along surfaces of the substrates. Then, the process chamber is substantially purged. A treatment gas is then provided onto the titanium nitride layers to remove chlorine from the titanium nitride layers. Then, the process chamber is again substantially purged. The substrates are revolved by a predetermined rotation angle. The process of forming the titanium nitride layers, substantially purging the process chamber a first time, providing the treatment gas, substantially purging the process chamber a second time, and rotating the substrates by a predetermined rotation angle may be repeatedly performed to obtain titanium nitride layers of a desired thickness. The predetermined rotation angle is represented by the following equation:

θ=360°/N (in which θ indicates the predetermined angle; and N represents the number of times the layer formation process has been repeated; i.e., the cycle of forming the titanium nitride layers, primarily purging the process chamber, providing the treatment gas, secondarily purging the process chamber and rotating the substrates.)

In another example embodiment of the present invention, the multiple substrates may be vertically stacked and spaced at predetermined (preferably equal) intervals, and the substrates are loaded generally in parallel into the process chamber.

In another example embodiment of the present invention, the first source gas and the second source gas may be provided into the process chamber through a plurality of first nozzles and a plurality of second nozzles respectively, such nozzles being disposed in a generally parallel array adjacent to the respective substrates.

In another example embodiment of the present invention, the first source gas may include a TiCl₄ gas.

In another example embodiment of the present invention, the second source gas may include an NH₃ gas.

In another example embodiment of the present invention, a time period ratio between the steps of forming the titanium nitride layers and the steps of providing the treatment gas may be in a range of about 1.0:1.0 to 4.0.

In another example embodiment of the present invention, a time period ratio between the steps of forming the titanium nitride layers and the step of primarily purging the chamber may be in a range of about 1.0:0.5.

In another example embodiment of the present invention, the process chamber may be maintained at a temperature of about 400 to about 600° C. during the sequential steps of forming the titanium nitride layers, primarily purging the process chamber, providing the treatment gas, secondarily purging the process chamber and rotating the substrates.

In another example embodiment of the present invention, the treatment gas may include an NH₃ gas.

According to one aspect of the present invention, there is provided an apparatus for forming a titanium nitride layer on a semiconductor element, the apparatus including a process chamber, a boat or a support member, a gas supply system, a driving unit, and a control unit. The boat is disposed in the process chamber and is adapted for supporting a plurality of substrates to be treated. The gas supply system provides a first source gas including titanium and chlorine, a second source gas including nitrogen, a treatment gas and purge gases as needed into the process chamber. The first source gas and second source gas are introduced to the process chamber in such a way that they flow along surfaces of the substrates to form titanium nitride layers on the substrates. The treatment gas then removes chlorine from the titanium nitride layers. The purge gases purge the process chamber. The driving unit revolves the substrates having titanium nitride layers by a predetermined rotation angle. The control unit controls the gas supply system and the driving unit such that the series of steps of sequentially providing the first source gas, the second source gas, the treatment gas and the purge gases to the process chamber from the gas supply system and rotating the substrates is alternately repeated. The predetermined rotation angle is represented by the following equation:

θ=360°/N (in which θ indicates the predetermined angle; and N represents the number of times the layer formation process has been repeated; i.e., the cycle of sequentially providing the first source gas, the second source gas, the treatment gas and the purge gases from the gas supply system.)

In an example embodiment of the present invention, the process chamber may have a generally vertically-oriented cylindrical shape including an open bottom face.

In another example embodiment of the present invention, the apparatus may further include a heating furnace disposed substantially to enclose the process chamber, a manifold connected to or adapted to engage with a lower portion of the process chamber, and a vertical driving unit for loading/unloading the boat into/out of the process chamber through the manifold. The heating furnace is used to heat and/or maintain the process chamber to/at a process temperature. The manifold may have a cylindrical shape including an open upper face and an open bottom face.

In another example embodiment of the present invention, the vertical driving unit may include a first motor for generating a rotation force, a lead screw revolved (turned) by the rotation force, and a horizontal arm coupled to the lead screw. The horizontal arm is vertically moved by the lead screw.

In another example embodiment of the present invention, the apparatus may further include a lid member disposed on the horizontal arm to open and close the open bottom face of the manifold, and a turntable disposed on the lid member to support the boat.

In another example embodiment of the present invention, the driving unit may further include a second motor mounted on the horizontal arm to generate a rotation force for rotating the boat, and a rotation axel coupled to the turntable through the horizontal arm and the lid member for transferring the rotation force to the boat.

In another example embodiment of the present invention, the apparatus may further include a heater for heating an inside region of the manifold.

In another example embodiment of the present invention, the substrates may be vertically loaded in the boat so as to be separated by predetermined intervals.

In another example embodiment of the present invention, the gas supply system may include a first gas supply unit for providing the first source gas, a second gas supply unit for providing the second source gas and the treatment gas, a third gas supply unit for providing the purge gases, a first gas supply line for transferring the first source gas into the process chamber, a second gas supply line for transferring the second source gas and the treatment gas into the process chamber, and connection lines for connecting the third gas supply unit to the first gas supply line and the second gas supply line.

In another example embodiment of the present invention, the gas supply system may further include a first nozzle pipe and a second nozzle pipe. The first nozzle pipe may be connected to the first gas supply line and vertically extend adjacent to the substrates in the process chamber. The first nozzle pipe may include a plurality of first nozzles for providing the first source gas and the purge gases onto the substrates. The second nozzle pipe may be connected to the second gas supply line and vertically extend generally in parallel relative to the first nozzle pipe in the process chamber. The second nozzle pipe may include a plurality of second nozzles for providing the second source gas and the treatment gas onto the substrates.

In still another example embodiment of the present invention, the first gas supply unit may include a first reservoir for providing a carrier gas, a second reservoir for storing TiCl₄ in the liquid phase, a vaporizer connected to the first and the second reservoirs to evaporate the liquid-phase TiCl₄, a valve installed in a first connection line that connects the first reservoir to the vaporizer, and a liquid mass flow controller installed in a second connection line that connects the second reservoir to the vaporizer. The valve may control a flow rate of the carrier gas, and the liquid mass flow controller may control a flow rate of the liquid-phase TiCl₄.

### BRIEF DESCRIPTION OF THE DRAWINGS

Example embodiments of the present invention will become readily apparent by reference to the following detailed description when considered in conjunction with the accompanying drawings wherein:

FIG. 1 is a schematic cross-sectional view illustrating an apparatus for forming a titanium nitride layer in accordance with an example embodiment of the present invention;

FIG. 2 is a block diagram illustrating a gas supply system for an apparatus for forming the titanium nitride layers as seen in FIG. 1;

FIG. 3 is a perspective view schematically illustrating a first nozzle pipe and a second nozzle pipe of the gas supply system shown in FIG. 2;

FIG. 4 is a block diagram illustrating a gas supply system in accordance with another example embodiment of the present invention;

FIG. 5 is a timing diagram illustrating a representative sequence of supply times of source gases, treatment gas, and purge gases using the gas supply system shown in FIG. 2; and

FIG. 6 is a flow chart illustrating a method of forming a titanium nitride layer in accordance with an example embodiment of the present invention.

### DETAILED DESCRIPTION OF THE EXAMPLE EMBODIMENTS

The present invention is described more fully hereinafter with reference to the accompanying drawings, in which illustrative embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions are sometimes exaggerated for clarity.

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, are sometimes used herein for ease of description to describe one element or feature's relationship to another element(s) or feature(s) as illustrated in the figures. It will be understood, however, that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations), and the spatially relative descriptors used herein should be interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to necessarily illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

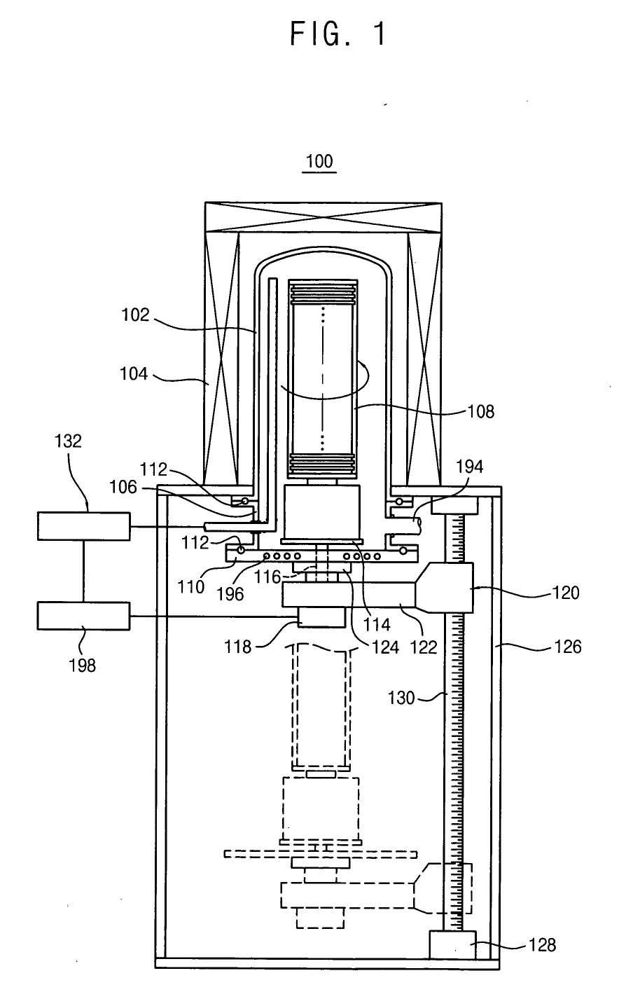

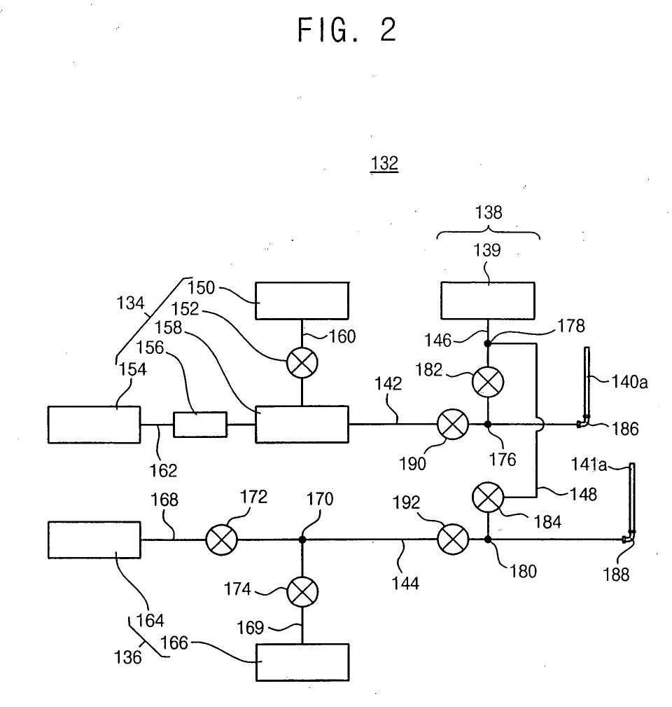

FIG. 1 is a schematic cross-sectional view illustrating an apparatus for forming a titanium nitride layer in accordance with an example embodiment of the present invention. FIG. 2 is a block diagram illustrating a gas supply system for an apparatus as illustrated in FIG. 1.

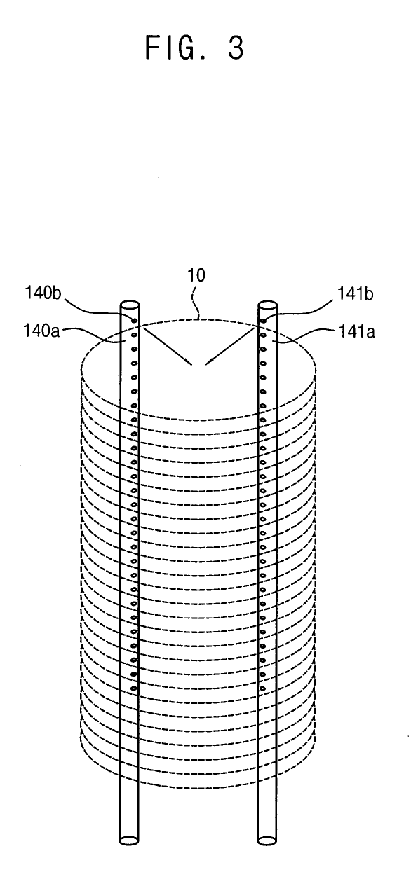

An apparatus 100 as shown in FIG. 1 may be advantageously employed for forming a titanium nitride layer on a semiconductor substrate 10 (for example, as illustrated in FIG. 3) such as a silicon wafer or a silicon on insulator (SOI) substrate.

Referring to FIG. 1, the apparatus 100 for forming the titanium nitride layers includes a process chamber 102 comprising a batch-type vertical reaction furnace. The process chamber 102 may have a vertically cylindrical shape including an open bottom face. The process chamber 102 may comprise a refractory material such as quartz.

The apparatus 100 additionally includes a heating furnace 104 that encloses the process chamber 102 and a manifold 106 having a cylindrical shape which is adapted to adjoin and/or engage with a lower portion of the process chamber 102. The manifold 106 may comprise a metal.

The apparatus 100 further comprises a boat or support member 108 for supporting a plurality of semiconductor substrates 10, the substrates being separated by predetermined (preferably equal) intervals along a vertical axis. The boat 108 is loaded into the process chamber 102 through the open bottom face of the process chamber 102 which is located below the manifold 106. A lid member 110 disposed below the manifold 106 closes the open bottom face of the process chamber 102 after the semiconductor substrates 10 are loaded into the process chamber 102. Sealing members 112 are disposed between the lid member 110 and the manifold 106 and also between the process chamber 102 and the manifold 106 so as to seal up the process chamber 102 during the layer formation process.

The boat 108 is preferably disposed on a turntable 114 coupled to an upper portion of a rotation axel 116. The apparatus 100 preferably further includes a rotation driving unit 118 and a vertical driving unit 126. The rotation driving unit 118 is disposed beneath a horizontal arm 122 of the vertical driving unit 120. The lid member 110 is positioned over the horizontal arm 122 of the vertical driving unit 120.

A mechanical seal 124 is disposed between the lid member 110 and the horizontal arm 122 of the vertical driving unit 120 to prevent leakage of gases through a gap between the rotation axel 116 and the lid member 110. The rotation axel 116 connects the turntable 114 to the rotation driving unit 118 through the mechanical seal 124 and the horizontal arm 122.

The manifold 106 is disposed at an upper portion of a load-lock chamber 126 (or a transfer chamber). The manifold 106 is adapted to move between the process chamber 102 and the load-lock chamber 126 along the vertical direction.

The vertical driving unit 120 includes the horizontal arm 122, a vertical driving member 128 and a driving axel 130. The vertical driving member 128 provides the horizontal arm 122 with a vertical driving force to move the horizontal arm 122 along the vertical direction. The vertical driving force is transferred to the horizontal arm 122 through the driving axel 130.

The vertical driving member 128 may include a first step motor, and the driving axel 130 may include a lead screw that is revolved by a rotation force provided from the first step motor. The horizontal arm 122 is coupled to the driving axel 130 so that the horizontal arm 122 may be vertically moved by the driving axel 130.

The rotation driving unit 118 may further include a second step motor. A driving gear is connected to such second step motor and an idler gear is coupled to the rotation axel 116. A timing belt is disposed between the driving gear and the idler gear. The second step motor thus provides a rotation force to the rotation axel 116 through the driving gear, the idler gear and the timing belt. In an example embodiment of the present invention, the idler gear may be directly coupled to the driving gear without the timing belt.

Referring to FIG. 2, a gas supply system 132 of the apparatus 100 (see FIG. 1) alternately provides source gases, a treatment gas or purge gases into the process chamber 102. The source gases and the treatment gas are provided onto the semiconductor substrates 10 loaded in the process chamber 102 by the boat 108 so as to form desired layers on the semiconductor substrates 10, respectively. The purge gases are introduced into the process chamber 102 to purge the process chamber 102 between the various layer formation steps.

In particular, the gas supply system 132 includes a first gas supply unit 134 (comprising elements 150, 152, 154, 156 and 158, as hereinafter described), a second gas supply unit 136 (comprising elements 164 and 166, as hereinafter described), and a third gas supply unit 138. The first and the second gas supply units 134 and 136 provide a first source gas, a second source gas and the treatment gas respectively and at the appropriate times onto the semiconductor substrates 10 to form titanium nitride layers on the semiconductor substrates 10 and to treat the titanium nitride layers formed on the semiconductor substrates 10. The third gas supply unit 138 comprising reservoir 139 provides the purge gases into the process chamber 102 to purge reaction and/or treatment gases together with byproducts from the chamber. In an example embodiment of the present invention, the first source gas is provided from the first gas supply unit 134. The second source gas and the treatment gas may both be provided from the second gas supply unit 136 if the second source gas and the treatment gas are the same.

The first source gas may include a TiCl₄ gas, and the second source gas may include an NH₃ gas. The first source gas and the second source gas may be mixed with a first carrier gas and a second carrier gas, respectively, and passed to the process chamber as mixed gas streams. The purge gases may include a substantially inert gas such as an argon (Ar) gas or a nitrogen (N₂) gas. The treatment gas is selected to effectively remove chlorine remaining in the titanium nitride layers formed by a reaction between the first source gas and the second source gas. The treatment gas may be substantially the same as the second source gas. The first and the second carrier gases may include a substantially inert gas such as an argon gas or a nitrogen gas. The first and the second carrier gases may be substantially to the same as the purge gases.

The gas supply system 132 is connected through gas supply lines to nozzle pipes 140a and 141a which are disposed in the manifold 106 (see FIG. 1). Particularly, the first gas supply unit 134 of the gas supply system 132 is connected to a lower end portion of a first nozzle pipe 140a, which is disposed in the manifold 106, through a first gas supply line 142. The second gas supply unit 136 is connected to a lower end portion of a second nozzle pipe 141a, which is also disposed in the manifold 106, through a second gas supply line 144. The third gas supply unit 138 is connected to the first gas supply line 142 and also to the second gas supply line 144 through a first connection line 146 and a second connection line 148, respectively. Accordingly, the purge gases can be introduced into the process chamber 102 through any or all of the first connection line 146, the second connection line 148, the first gas supply line 142 and the second gas supply line 144.

In an example embodiment of the present invention, the third gas supply unit 138, comprising reservoir 139, may be separately connected to one of the first or the second gas supply lines 142 and 144 through an additional gas supply line (not shown) although the third gas supply unit 138 is already connected to both of the first and the second gas supply lines 142 and 144 through the first and the second connection lines 146 and 148 as shown in FIG. 2.

The first gas supply unit 134 includes a first reservoir 150, a first valve 152, a second reservoir 154, a liquid mass flow controller 156, and a vaporizer 158. The first carrier gas is provided from the first reservoir 150. The first valve 152 adjusts a flow rate of the first carrier gas. The second reservoir 154 stores the liquid-phase TiCl₄ gas. The liquid mass flow controller 156 controls a flow rate of the liquid-phase TiCl₄ gas. The vaporizer 158 evaporates the liquid-phase TiCl₄ gas into a gaseous or vaporized phase. Alternatively, the first gas supply unit 134 may include a bubbler instead of the vaporizer 158 to evaporate the liquid-phase TiCl₄ gas.

The first reservoir 150 is connected to the vaporizer 158 through a third connection line 160. The first valve 152 is installed in the third connection line 160. The second reservoir 154 is connected to the vaporizer 158 through a fourth connection line 162. The liquid mass flow controller 156 is installed in the fourth connection line 162.

The liquid-phase TiCl₄ gas is evaporated in the vaporizer 158, and then the mixed gas stream containing the evaporated TiCl₄ gas (i.e., the TiCl₄ gas in a gas phase) and the first carrier gas is provided onto the semiconductor substrates 10 through the first gas supply line 142 and first nozzles of the first nozzle pipe 140a.

The second gas supply unit 136 includes a third reservoir 164 and a fourth reservoir 166. The third reservoir 164 provides the second carrier gas into the process chamber 102, and the fourth reservoir 166 provides the NH₃ gas into the process chamber 102. The second gas supply unit 136 is connected to the second nozzle pipe 141a through the second gas supply line 144.

The second gas supply line 144 is connected to the third reservoir 164 through a fifth connection line 168, and to the fourth reservoir 166 through a sixth connection line 169. A first connecting member 170 connects the second gas supply line 144 to the fifth connection line 168 and the sixth connection line 169. A second valve 172 is installed in the fifth connection line 168 to adjust a flow rate of the second carrier gas. A third valve 174 is installed in the sixth connection line 169 to control a flow rate of the NH₃ gas.

The third gas supply unit 138 includes a fifth reservoir 139 for providing the purge gases into the process chamber 102. The first connection line 146 is connected to the first gas supply line 142 through a second connecting member 176. One end portion of the second connection line 148 is connected to the first connection line 146 through a third connecting member 178, and another end portion of the second connection line 148 is connected to the second gas supply line 144 through a fourth connecting member 180. A fourth valve 182 is installed in the first connection line 146 between the second connecting member 176 and the third connecting member 178. A fifth valve 184 is installed in the second connection line 148. In the manifold 106, the first gas supply line 142 and the second gas supply line 144 are connected to the first nozzle pipe 140a and the second nozzle pipe 141a, respectively, through a fifth connecting member 186 and a sixth connecting member 188, respectively.

As shown in FIG. 2, a sixth valve 190 is installed in the first gas supply line 142 between the vaporizer 158 and the second connecting member 176. The sixth valve 190 controls a flow rate of the combined stream of first source gas and first carrier gas. A seventh valve 192 is installed in the second gas supply line 144 between the first connecting member 170 and the second connecting member 180. The seventh valve 192 regulates a flow rate of the combined stream of second source gas and carrier gas. In an exemplary embodiment of the present invention, the first carrier gas, the second carrier gas and the purge gases may be the same and, thus, may be provided from one reservoir, although as shown in FIG. 2 these gases are separately provided from different reservoirs.

The TiCl₄ gas is condensed at a temperature below about 70° C. The condensed TiCl₄ gas may contaminate the elements of the apparatus 100 for forming the titanium nitride layers. The TiCl₄ gas may react with the NH₃ gas at a temperature of about 130° C. or below to form a powder of NH₄Cl. Also, as previously discussed, the TiCl₄ gas may react with the NH₃ gas at a temperature between about 280 to about 350° C. to form a titanium layer or titanium nitride layer. Accordingly, the first gas supply line 142 for transferring the mixed gas stream including TiCl₄ gas may advantageously be maintained at a temperature of about 150 to about 250° C. in order to prevent a condensation of the TiCl₄ gas and/or a reaction between the TiCl₄ gas and the NH₃ gas in the first gas supply line 142.

In an example embodiment of the present invention, a first heating jacket (not shown) may be installed around the first gas supply line 142 so that the first gas supply line 142 may be maintained at a constant temperature. For example, the first gas supply line 142 may have a temperature of about 200° C., which the first heating jacket helps to maintain.

When the second source gas has a temperature substantially lower than that of the first source gas, an undesired reaction between the first source gas and the second source gas may occur in the process chamber 102 because of a temperature difference between the first source gas and the second source gas. Thus, the second source gas is advantageously maintained at a temperature substantially identical to that of the first source gas. According to an example embodiment of the present invention, a second heating jacket (not shown) may be installed around the second gas supply line 144 to control the temperature of the second source gas. For example, the second gas supply line 144 may have a temperature of about 200° C., which the second heating jacket helps to maintain.

For such reasons, the purge gases may preferably also have a temperature substantially identical to that of the first source gas. In an example embodiment of the present invention, a third heating jacket (not shown) and a fourth heating jacket (not shown) may be respectively installed around the first connection line 146 and the second connection line 148 so as to heat and/or maintain a temperature of the purge gases.

FIG. 3 is a perspective view schematically illustrating the first nozzle pipe 140a and the second nozzle pipe 141a which are shown connecting to the gas supply system 132 in FIG. 2.

Referring to FIGS. 1 and 3, the first nozzle pipe 140a is adjacent to the plurality of semiconductor substrates 10 loaded in the boat 108. The first nozzle pipe 140a extends along the vertical direction from the first gas supply line 142 (FIG. 2). The first nozzle pipe 140a includes a plurality of first nozzles 140b for providing the mixed gas stream containing the first source gas onto the semiconductor substrates 10. The first nozzles 140b are disposed at lateral portions of the first nozzle pipe 140a along the vertical direction and are preferably separated by or spaced (at preferably equal) predetermined intervals so that the mixed gas stream containing the first source gas sprayed from the first nozzles 140b flows along surfaces of the semiconductor substrates 10 loaded in the boat 108. Particularly, after the first nozzles 140b provide the first source gas into spaces among and between the semiconductor substrates 10, the mixed gas stream containing the first source gas sprayed from the first nozzles 140b flows toward central portions of the semiconductor substrates 10.

The second nozzle pipe 141a is also disposed adjacent to the semiconductor substrates 10 loaded in the boat 108, and extends generally in parallel relative to the first nozzle pipe 140a. The second nozzle pipe 141a includes a plurality of second nozzles 141b for spraying the mixed gas stream containing the second source gas onto the semiconductor substrates 10. The second nozzles 141b are disposed at lateral portions of the second nozzle pipe 141a along the vertical direction and are preferably separated by or spaced at predetermined intervals so that the mixed gas stream containing the second source gas sprayed from the second nozzles 141b flows along the surfaces of the semiconductor substrates 10 loaded in the boat 108. In particular, after the second nozzles 141b provide the mixed gas stream containing the second source gas into the spaces among and between the semiconductor substrates 10, the mixed gas stream containing the second source gas sprayed from the second nozzles 141b flows toward central portions of the semiconductor substrates 10.

An angle between spray directions of the mixed gas stream containing the first source gas and the mixed gas stream containing the second source gas may be in a range of about 20 to about 80°. The first nozzle pipe 140a and the second nozzle pipe 141a may be separated from central axis of the process chamber 102 and of the array of semiconductor substrates 10 by substantially identical distances, respectively. The first nozzle pipe 140a and the second nozzle pipe 141a may, for example, have inner diameters of about 2.5 to about 15 mm. Each of the first nozzles 140b and the second nozzles 141b may, for example, have an inner diameter of about 0.5 to about 2.0 mm. In an example embodiment of the present invention, the first and the second nozzle pipes 140a and 141a have inner diameters of about 5 mm, respectively. Also, in an example embodiment, each of the first and the second nozzles 140b and 141b has an inner diameter of about 1.5 mm.

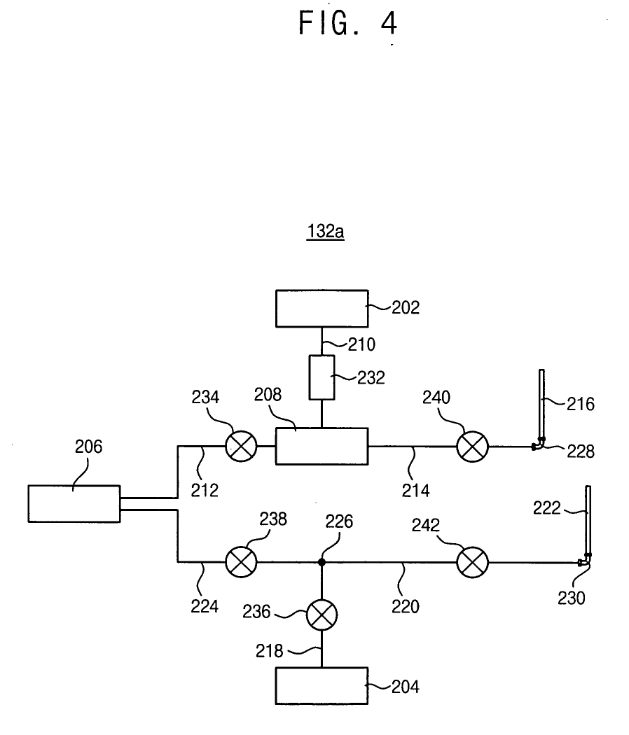

FIG. 4 is a block diagram illustrating a gas supply system in accordance with another example embodiment of the present invention.

Referring to FIGS. 1 and 4, a gas supply system 132a as shown in FIG. 4 includes a first reservoir 202, a second reservoir 204, a third reservoir 206 and a vaporizer 208. The first reservoir 202 stores liquid-phase TiCl₄, and the second reservoir 204 provides an NH₃ gas for introduction into the process chamber 102. The third reservoir 206 provides an argon gas or a nitrogen gas for introduction into the process chamber 102, and the vaporizer 208 evaporates the liquid-phase TiCl₄ to form a TiCl₄ gas. The argon gas or the nitrogen gas supplied from the third reservoir 206 may be used as a first carrier gas and/or a second carrier gas for mixing with and carrying the TiCl₄ gas and the NH₃ gas respectively. Additionally, the argon gas or the nitrogen gas provided from the third reservoir 206 may also be used as purge gases for purging the process chamber 102.

The first reservoir 202 as shown in FIG. 4 is connected to the vaporizer 208 through a first connection line 210, and the third reservoir 206 is connected to the vaporizer 208 through a second connection line 212. The vaporizer 208 is coupled to a first nozzle pipe 216 through a first gas supply line 214. After liquid-phase TiCl₄ is provided from the first reservoir 202 through the first connection line 210, the liquid-phase TiCl₄ is mixed with the carrier gas and evaporated in the vaporizer 208. Then, the mixed gas stream containing the evaporated TiCl₄ (i.e., the TiCl₄ gas) together with the argon gas or the nitrogen gas supplied from the third reservoir 206 is provided to the semiconductor substrates 10 in the process chamber 102 through the first gas supply line 214 and the first nozzle pipe 216.

The second reservoir 204 is connected to a second nozzle pipe 222 through a third connection line 218 and a second gas supply line 220. The third reservoir 206 is connected to the second nozzle pipe 222 through a fourth connection line 224 and the second gas supply line 220. That is, the third and the fourth connection lines 218 and 224 connect the second reservoir 204 and the third reservoir 206 respectively to the second gas supply line 220.

The third connection line 218, the fourth connection line 224 and the second gas supply line 220 are connected to one another through a first connecting member 226. The first gas supply line 214 and the second gas supply line 220 are connected to the first nozzle pipe 216 and the second nozzle pipe 222 respectively through a second connecting member 228 and a third connecting member 230, respectively.

A liquid mass flow controller 232 is installed in the first connection line 210 to adjust a flow rate of liquid-phase TiCl₄. A first valve 234 is installed in the second connection line 212 to control a flow rate of the argon gas or a flow rate of the nitrogen gas which is employed as either the first carrier gas or the purge gases or both. A second valve 236 is mounted in the third connection line 218 to control a flow rate of the NH₃ gas from the reservoir 204. A third valve 238 is installed in the fourth connection line 224 to control the flow rate of the argon gas or the flow rate of the nitrogen gas which is employed as either the second carrier gas or the purge gases or both.

In an example embodiment of the present invention, a fourth valve 240 and a fifth valve 242 may be installed in the first gas supply line 214 and in the second gas supply line 220, respectively. The fourth valve 240 controls a flow rate of the mixed gas stream containing the first source gas, and the fifth valve 242 regulates a flow rate of the mixed gas stream containing the second source gas.

Referring again to FIG. 1, a vacuum pump (not shown) is connected to the manifold 106 through a vacuum line 194 and an isolation valve (not shown) so as to vacuumize the process chamber 102. A heating furnace 104 is disposed adjacent to a sidewall and a ceiling or upper region of the process chamber 102. The process chamber 102 may, for example, be operated at a pressure of about 0.3 to about 1.0 Torr and a temperature of about 400 to about 600° C. during formations of the titanium nitride layers on the semiconductor substrates 10. For a specific example, the process chamber 102 has a temperature of about 500° C.

An inside region of the manifold 106 may have a temperature substantially lower than that of an inside region of the process chamber 102. A heater 196 may be provided in the lid member 110 to compensate for such a temperature difference between the inside region of the manifold 106 and the inside region of the process chamber 102. The heater 196 heats the inside region of the manifold 106 so that the inside of the manifold 106 has a temperature substantially identical to that of the inside of the process chamber 102. The heater 196 may include an electrical resistance coil. In an example embodiment of the present invention, the heater 196 may be disposed inside a sidewall of the manifold 106. Alternatively, the heater 196 may be mounted on an inner sidewall of the manifold 106.

A control unit 198 controls the gas supply system 132, the vertical driving unit 120 and the rotation driving unit 118. After loading the boat 108 including the semiconductor substrates 10 into the process chamber 102, the flow rates and flow times of the gases provided from the gas supply system 132 are all preferably controlled by the control unit 198. The control unit 198 can further control the rotation speed of the semiconductor substrates 10 so as to uniformly form the titanium nitride layers on the semiconductor substrates 10. In an example embodiment of the invention, the control unit 198 properly controls both rotation of the boat 108 and the supply of the gases from the gas supply system 132 such that the rotation of the boat 108 and the supply of the gases are alternately repeated.

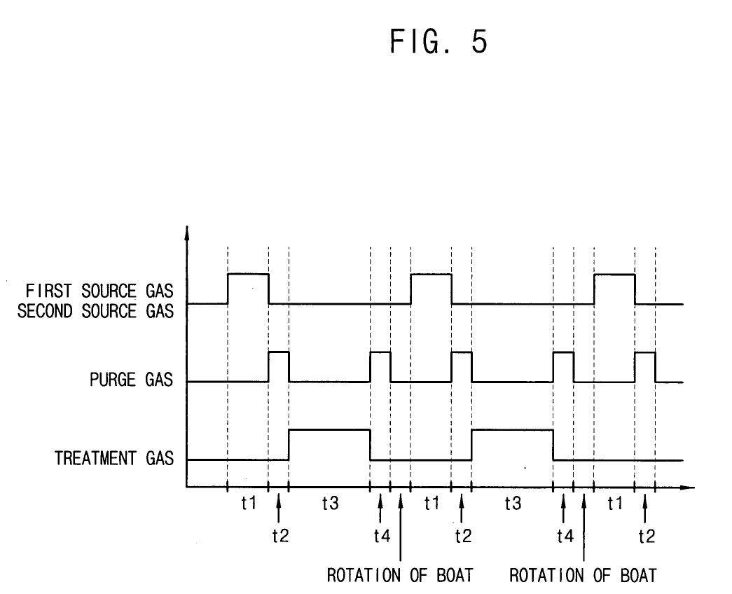

FIG. 5 is a timing diagram illustrating a representative sequence of supply times of source gases, purge gases and a treatment gas using the gas supply system 132 as shown in FIG. 2.

Referring to FIGS. 1, 2 and 5, the first source gas and the second source gas are provided onto the semiconductor substrates 10 for about a first time period t1 through the first nozzles 140b and the second nozzles 141b, thereby forming titanium nitride layers on the semiconductor substrates 10.

A first purge gas is introduced in the process chamber 102 for about a second time period t2 through both the first nozzles 140b and the second nozzles 141b so as to primarily substantially purge the process chamber 102.

After primarily purging the process chamber 102, a treatment gas is provided onto the semiconductor substrates 10 for a third time period t3 to remove chlorine ions remaining in the previously-formed titanium nitride layers. The treatment gas may be substantially identical to the second source gas. The treatment gas may be introduced into the process chamber 102, for example, through the second nozzles 141b (FIG. 3). Then, a second purge gas is introduced into the process chamber 102 for a fourth time period t4 through the first nozzles 104b and/or the second nozzles 141b so as to secondarily substantially purge the process chamber 102.

After performing a unit cycle (consisting of the sequential steps of providing the first source gas and the second source gas, introducing the first purge gas, providing the treatment gas, and introducing the second purge gas), the control unit 198 revolves the boat 108 including the semiconductor substrates 10 by a previously set angle. After rotation of the boat 108, the unit cycle is repeated. After each unit cycle, the boat 108 and the semiconductor substrates 10 are rotated by the pre-established angle before the next unit cycle is performed. The process of performing a unit cycle and rotating the boat is repeated multiple times in order to obtain titanium nitride layers having a desired thickness. The control unit 198 controls performance of the unit cycle and the rotation of the boat 108 so that the performance of the unit cycle and the rotation of the boat 108 are alternately performed.

To form the titanium nitride layers having uniform thickness, the rotation angle by which the boat 108 is rotated after each unit cycle may be obtained by the following equation:
θ=360°/N

In the above equation, θ represents a previously set rotation angle of the boat 108, and N represents the number of unit cycles to be performed.

In repeatedly performing the unit cycles, the semiconductor substrates 10 are revolved by the previously set rotation angle so that titanium nitride layers having substantially uniform thicknesses may be formed on the semiconductor substrates 10. That is, using the techniques of this invention results in forming titanium nitride layers having substantially uniform thicknesses irrespective of the spray directions of the first and the second source gases.

When the third time period t3 of the treatment gas step is increased, the chlorine ions contained in the titanium nitride layer may be efficiently and even more completely removed. However, a process time period for the overall process of forming the titanium nitride layers would also increase in accordance with an increase of the third time period t3 for carrying out the treatment gas step. On the other hand, the chlorine ions in the titanium nitride layers may not be sufficiently removed when the first time period t1 for carrying out the first and the second source gases step is substantially greater than the third time period t3 of the treatment gas step. Accordingly, to achieve a suitable balance among the length of each source gas step, the overall layer formation time, and the effective removal of chlorine ions from the titanium nitride layers, it is preferred to maintain a ratio among the first time period t1, the second time period t2, the third time period t3 and the fourth time period t4 in a range of about 1.0:0.5:1.0 to 4.0:0.5. For example, when the first time period t1 for the process step of providing the first and the second source gases is about one minute, the second time period t2 and the fourth time period t4 might be about 30 seconds each, and the third time period t3 might range from about one to about four minutes.

In one specific example embodiment of the present invention, a titanium nitride layer is formed by providing a first source gas and a second source gas for a period of about one minute, and then the titanium nitride layer is treated by providing a treatment gas for a period of about two minutes. This titanium nitride layer demonstrates a specific resistance of about 155 μΩm.

In another specific example embodiment of the present invention, after a titanium nitride layer is formed by providing a first source gas and a second source gas for a period of about five seconds, the titanium nitride layer is treated by providing a treatment gas for a period of about 3 minutes. This titanium nitride layer demonstrates a specific resistance of about 250 μΩm.

As described above, the titanium nitride layer may demonstrate a reduced specific resistance when the chlorine ions are removed from the titanium nitride layer using the treatment gas step. Since the treated titanium nitride layer has such a reduced specific resistance, the titanium nitride layer may be efficiently formed in the process chamber 102 at a temperature of about 400 to about 600° C., and step coverage of the titanium nitride layer may also be improved utilizing the techniques of this invention.

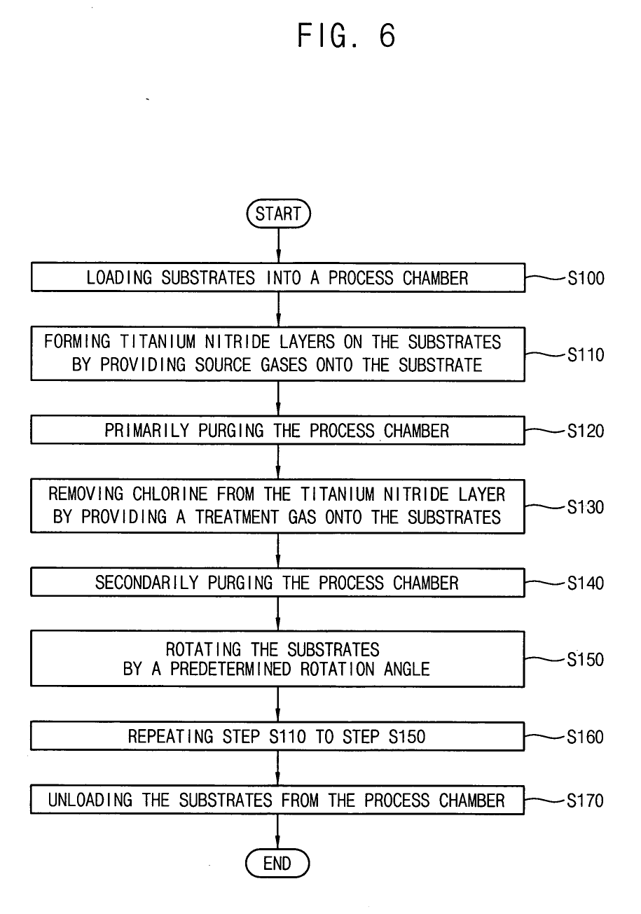

FIG. 6 is a flow chart illustrating a method of forming a titanium nitride layer in accordance with an example embodiment of the present invention.

Referring to FIGS. 1, 2, 3 and 6, the semiconductor substrates 10 are loaded into the process chamber 102 in step S100. The semiconductor substrates 10 are vertically loaded into the boat 108, separated by predetermined intervals or spacing. The surfaces of the semiconductor substrates 10 are substantially horizontally disposed in the boat 108. The boat 108 including the semiconductor substrates 10 is loaded into the process chamber 102 through the manifold 106 by means of the vertical driving unit 120. The process chamber 102 may have a temperature of about 500° C., which is maintained by the heating furnace 104 and the heater 196.

In an example embodiment of the present invention, the semiconductor substrates 10 comprise semiconductor structures for use in fabricating semiconductor devices. For example, each of the semiconductor structures may include a transistor and a capacitor, having a dielectric layer and a lower electrode. The transistor may also include a gate structure and impurity regions serving as source/drain regions. The lower electrode of the capacitor may be electrically connected to one of the impurity regions. The dielectric layer of the capacitor may be formed on the lower electrode. The lower electrode may be formed using polysilicon doped with impurities, and the dielectric layer may be formed using hafnium oxide (HfO₂). These and other similar semiconductor structures are familiar to those skilled in the art.

In step S110, the first source gas and the second source gas are provided through the first nozzles 140b and the second nozzles 141b onto the semiconductor substrates 10 to thereby form the titanium nitride layers on the semiconductor substrates 10. During formations of the titanium nitride layers, the liquid mass flow controller 156 controls the flow rate of the TiCl₄ gas, for example at a rate of about 200 mgm, and the first valve 152 adjusts the flow rate of the first carrier gas, for example to be about 0.5 slm. Additionally, the second valve 172 adjusts the flow rate of the second carrier gas, for example to be about 0.5 slm, and the third valve 174 controls the flow rate of the NH₃ gas, for example to be about 0.5 slm. The control unit 198 can be arrange to control the liquid mass flow controller 156 and the first, second, and third valves 152, 172 and 174, respectively. The first and the second source gases may be provided into the process chamber 102, for example for a period of about one minute. When the first and the second source gases are provided onto the semiconductor substrates 10 for about one minute, each of the titanium nitride layers on the semiconductor substrates 10 have been found to demonstrate a thickness of about 17 Å.

In step S120, the first purge gas is provided into the process chamber 102 to remove remaining first and second source gases and reaction by-products from the process chamber 102. The first purge gas may be introduced into the chamber 102 for a period of, for example, about 30 seconds through the first nozzles 140b and the second nozzles 141b (see FIG. 3). The fourth and the fifth valves 182 and 184 (see FIG. 2) control the flow rate of the first purge gas to be for example about 1 slm.

In step S130, the treatment gas is provided into the process chamber 102 through the second nozzles 141b to remove the chlorine ions remaining in the titanium nitride layers. In one example embodiment, the treatment gas may be substantially identical to the second source gas. The treatment gas may be provided onto the semiconductor substrates 10 for example for a period of about two minutes. When the chlorine ions are substantially removed from the titanium nitride layer positioned on the dielectric layer, the treated titanium nitride layer may demonstrate a reduced specific resistance and an undesired reaction between the titanium nitride layer and the dielectric layer may be prevented or at least minimized. For example, the formation of hafnium (IV) chloride (HfCl₄), generated by a reaction between hafnium oxide in the dielectric layer and the chlorine ions in the titanium nitride layer, may be prevented by the treatment gas step of the present invention so that the dielectric layer may retain improved dielectric characteristics.

In step S140, the second purge gas is introduced into the process chamber 102 to remove remaining treatment gas and reaction by-products caused by the chlorine ions and the treatment gas. The second purge gas may be provided into the process chamber 102 for example for a period of about 30 seconds through the first and the second nozzles 140b and 141b. The fourth and the fifth valves 182 and 184 control the flow rate of the second purge gas to be for example about 1 slm.

In the partial unit cycle which comprises the set of sequential steps from step S100 to step S140, the control unit 198 preferably controls the liquid mass flow controller 156 as well as the first to the fifth valves 152, 172, 174, 182 and 184 (see FIG. 2). The process chamber 102 may be maintained at a pressure of about 0.3 to about 1 Torr and at a temperature of about 500° C.

In step S150, the boat 108 having the semiconductor substrates 10 is revolved by a previously set rotation angle. For example, the rotation angle of the boat 108 is about 10° when the number of the unit cycles is about 36. The number of unit cycles performed on each set of substrates 10 may vary in accordance with the desired thicknesses of the final titanium nitride layers, and thus the rotation angle for rotating the boat 108 may also vary.

In step S160, it is determined whether the complete unit cycle, which comprises the set of sequential steps from step S100 to step S150, is to be repeatedly performed until titanium nitride layers having the desired thicknesses have been formed on the semiconductor substrates 10. The control unit 198 controls the liquid mass flow controller 156 and the valves 152, 172, 174, 182 and 184 so that the partial unit cycle (steps S100 to S140) and the rotation step (step S150) comprising rotating the boat 108 are alternately executed.

In step S170, the semiconductor substrates 10 having the titanium nitride layers of the desired thicknesses are unloaded from the process chamber 102. That is, the boat 108 having the semiconductor substrates 10 is carried out of the process chamber 102 into the load-lock chamber 126 (see FIG. 1) by the vertical driving unit 120.

According to the present invention, titanium nitride layers are formed on semiconductor substrates using source gases, and then the titanium nitride layers are treated using a treatment gas to remove chlorine ions remaining in the titanium nitride layers. Thus, the titanium nitride layers formed according to the present invention may have relatively low specific resistance and good step coverage. In addition, generation of undesired particles caused by a reaction between the chlorine ions remaining in the titanium nitride layers and ingredients in an underlying substrate layer may be effectively prevented so that the underlying layer, such as a dielectric layer, may retain improved characteristics and avoid being damaged.

Since the chlorine ions are removed from the titanium nitride layers by the treatment gas, processes for forming the titanium nitride layers in accordance with the present invention may be performed at a relatively low temperature (e.g., about 500° C.). Furthermore, the titanium nitride layers formed in accordance with the present invention may have more uniform thicknesses because a boat carrying the semiconductor substrates is revolved by a predetermined rotation angle between each layer deposition cycle in the formation of the titanium nitride layers.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with all reasonable equivalents of the claims as understood by those skilled in this art to be included therein.

What is claimed is:

1. A method of forming titanium nitride layers on one or more substrates comprising:
(a) forming titanium nitride layers on substrates loaded in a process chamber by bringing a first source gas, which includes titanium and chlorine, and a second source gas, which includes nitrogen, into contact with the substrates, wherein the first source gas and the second source gas flow along surfaces of the substrates;
(b) substantially purging the process chamber a first time;
(c) bringing a treatment gas into contact with the titanium nitride layers to remove chlorine from the titanium nitride layers;
(d) substantially purging the process chamber a second time;
(e) rotating the substrates by a predetermined rotation angle; and
(f) repeatedly performing the steps (a) to (e) until the titanium nitride layers attain the desired thicknesses, wherein the predetermined rotation angle in the rotation step is represented by the following equation:
θ=360°/N (wherein θ represents the predetermined rotation angle and N represents the number of times the process steps (a) to (e) are to be repeated.

2. The method of claim 1, wherein the substrates are vertically stacked and loaded substantially in parallel into the process chamber.

3. The method of claim 2, wherein the first source gas and the second source gas are provided into the process chamber through a plurality of first nozzles and a plurality of second nozzles, respectively, arranged in generally parallel arrays disposed adjacent to the substrates.

4. The method of claim 1, wherein the first source gas consists essentially of a TiCl₄ gas.

5. The method of claim 1, wherein the second source gas consists essentially of an NH₃ gas.

6. The method of claim 1, wherein a time period ratio between the time period used for the step of forming the titanium nitride layers and the time period used for the step of providing the treatment gas is in a range of about 1.0:1.0 to 4.0.

7. The method of claim 1, wherein a time period ratio between the time period used for the step of forming the titanium nitride layers and the time period used for the step of primarily purging the process chamber is in a range of about 1.0:0.5.

8. The method of claim 1, wherein the process chamber is maintained at a temperature of about 400 to about 600° C. during the steps of forming the titanium nitride layers, primarily purging the process chamber, providing the treatment gas, secondarily purging the process chamber and rotating the substrates.

9. The method of claim 1, wherein the treatment gas consists essentially of an NH₃ gas.

10. An apparatus for forming titanium nitride layers on one or more substrates, the apparatus comprising:
a process chamber;
a boat disposed in the process chamber for supporting a plurality of substrates;
a gas supply system for sequentially providing to the process chamber: a first source gas including titanium and chlorine and a second source gas including nitrogen; a first purge gas; a treatment gas; and a second purge gas, such that the first source gas and second source gas flow along surfaces of the substrates to form titanium nitride layers on the substrates, the treatment gas removes chlorine from the titanium nitride layers, and the purge gases purge the process chamber between other steps;
a driving unit for rotating the substrates by a predetermined rotation angle; and
a control unit for controlling the gas supply system and the driving unit so that the steps of forming titanium nitride layers and rotating the substrates are alternately repeated,
wherein the predetermined rotation angle is represented by the following equation:
θ=360°/N (wherein θ represents the predetermined rotation angle and N represents the number of times the titanium nitride formation process needs to be repeated to obtain the desired final titanium nitride layer thicknesses.

11. The apparatus of claim 10, wherein the process chamber has a vertical cylindrical shape including an open bottom face.

12. The apparatus of claim 11, further comprising:
a heating furnace disposed substantially to enclose the process chamber for heating the process chamber to a process temperature;
a manifold in engagement with a lower portion of the process chamber, the manifold having a cylindrical shape including an open upper face and an open bottom face; and
a vertical driving unit for loading/unloading the boat into/out of the process chamber through the manifold.

13. The apparatus of claim 12, wherein the vertical driving unit comprises:
a motor for generating a first rotation force;
a lead screw revolved by the first rotation force; and
a horizontal arm coupled to the lead screw, the horizontal arm being vertically moved by the lead screw.

14. The apparatus of claim 13, further comprising:
a lid member disposed on the horizontal arm to open and close the open bottom face of the manifold; and
a turntable disposed on the lid member to support the boat.

15. The apparatus of claim 14, wherein the driving unit further comprises:
a second motor mounted on the horizontal arm to generate a second rotation force for rotating the boat; and
a rotation axel coupled to the turntable through the horizontal arm and the lid member for transferring the second rotation force to the boat.

16. The apparatus of claim 12, further comprising a heater for heating an inside region of the manifold.

17. The apparatus of claim 10, wherein the substrates are vertically loaded in the boat, and are separated by predetermined intervals.

18. The apparatus of claim 17, wherein the gas supply system comprises:
a first gas supply unit for providing the first source gas;
a second gas supply unit for providing the second source gas and the treatment gas;
a third gas supply unit for providing the purge gases;
a first gas supply line for transferring the first source gas into the process chamber;
a second gas supply line for transferring the second source gas and the treatment gas into the process chamber; and
connection lines for connecting the third gas supply unit to the first gas supply line and the second gas supply line.

19. The apparatus of claim 18, wherein the gas supply system further comprises:
a first nozzle pipe connected to the first gas supply line and vertically extending adjacent to the substrates in the process chamber, the first nozzle pipe including a plurality of first nozzles for alternately providing the first source gas and the purge gases onto the substrates; and
a second nozzle pipe connected to the second gas supply line and extending in parallel relative to the first nozzle pipe in the process chamber, the second nozzle pipe including a plurality of second nozzles for alternately providing the second source gas and the treatment gas onto the substrate.

20. The apparatus of claim 18, wherein the first gas supply unit comprises:
a first reservoir for providing a carrier gas;
a second reservoir for storing TiCl₄ in a liquid phase;
a vaporizer connected to the first and the second reservoirs to evaporate the TiCl₄ from the liquid phase into a vaporized phase;
a valve installed in a first connection line that connects the first reservoir to the vaporizer, the valve controlling a flow rate of the carrier gas; and
a liquid mass flow controller installed in a second connection line that connects the second reservoir to the vaporizer, the liquid mass flow controller controlling a flow rate of the liquid-phase TiCl₄.
